(19) United States
(12) Patent Application Publication
(10) Pub. No.: US 2012/0241810 A1
(43) Pub. Date: Sep. 27, 2012

(54) PRINTING CIRCUIT BOARD WITH MICRO-RADIATORS

(76) Inventor: Zheng Wang, Zhuhai (CN)

(21) Appl. No.: 13/514,998

(22) PCT Filed: Jan. 5, 2011
(86) PCT No.: PCT/CN11/70042

§ 371 Date: Jun. 11, 2012

(30) Foreign Application Priority Data
Nov. 30, 2010 (CN) 201010564877.5

(51) Int. Cl. H01L 33/62; H05K 1/09

(52) U.S. Cl. 257/99; 174/252; 257/E33.066

(57) ABSTRACT

The present invention relates to a printing circuit board with micro-radiators. The printing circuit board includes a substrate, the substrate includes multi-layer copper clad plates and multi-layer prepregs, the multi-layer copper clad plates and the multi-layer prepregs are cross-laminated, the printing circuit board also includes at least one cylindrical micro-radiator embedded into a cylindrical hole of the substrate, the height of the insulating microradiator is equal to the thickness of the substrate, an upper surface and a lower surface of the micro-radiator are covered by copper foils, a heating element is installed on one of the surfaces of the insulating micro-radiator, the other surface of the insulating micro-radiator is isolated from other circuits of the printing circuit board. The present invention combines the micro-radiator with high thermal conductivity and traditional rigid printing circuit board. The present invention has the advantages of high thermal conductivity and stable heat transfer.

### FIELD OF THE INVENTION

The present invention relates to printing circuit boards, particularly, the present invention relates to a printing circuit board with micro-radiators.

### BACKGROUND OF THE INVENTION

Printing circuit boards (PCBs) are one of important elements in electronics industry. PCBs are used as mechanical support elements for the electronic components, and realize electrical connection among the electronic components. In addition, graphics and numbers of the components can be printed on the PCBs, it is convenient for furnishing, checking or maintaining the components. The PCBs are used in almost every electronic device, such as electronic watch, calculator, computer, communication electronics device, military weapon systems.

Traditional PCBs are plated through hole structure, insulation material among layers is FR4 material, the thermal conductivity of the insulation material is 0.4 W/mk. In recent years, the thermal conductivity of the insulation material is 1.3-2.2 W/mk. When plenty of integrated circuits (especially high power LED) are installed on the printing circuit board, the thermal conductivity of the printing circuit board come up to tens or hundreds of W/mk. Obviously, it is far beyond the thermal conductivity of the insulation material of the prior art.

Therefore, there are some shortcomings in the prior art.

### SUMMARY OF THE INVENTION

An object of the present invention is to provide a printing circuit board with micro-radiators.

The object of the present invention is realized by use the technical solutions as follows:

A printing circuit board includes a substrate, the substrate includes multi layer copper clad plates and multi-layer prepregs, and the multi-layer copper clad plates and the multi-layer prepregs are cross-laminated, and at least one cylindrical micro-radiator is embedded into a cylindrical hole of the substrate, the height of the micro-radiator is equal to the thickness of the substrate, and an upper surface and a lower surface of the micro-radiator are covered copper foils, a heating element is installed on the upper surface of the micro-radiator, the lower surface of the micro-radiator is electrically insulated from circuits of the printing circuit board.

Compared with the prior art, the present invention combines the micro-radiator with high thermal conductivity and traditional rigid printing circuit board. The present invention has the advantages of high thermal conductivity and stable heat transfer. The present invention also has the advantages of routing flexibility and reliable electrical connections. The heat coming from the heating elements can be conducted out of the printing circuit board in time and effectively. The present invention is the ideal carrier board for the heating element and heating element array.

### DETAILED DESCRIPTION OF THE DRAWINGS

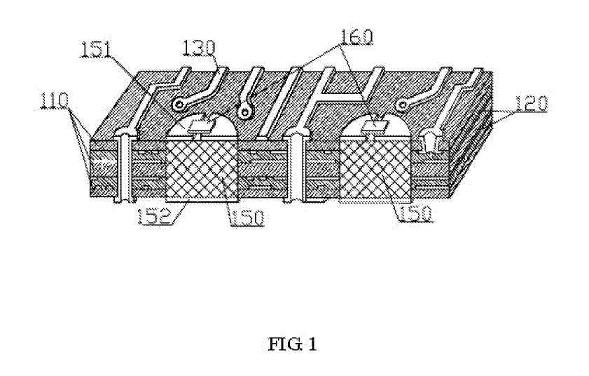

FIG. 1 is a schematic cross-sectional view illustrating the printing circuit board with micro-radiators of the present invention.

### DETAILED DESCRIPTION OF THE PREFERRED EMBODIMENT

As shown in FIG. 1, the printing circuit board is a rigid PCB, and includes a substrate. The substrate includes 3 layers of copper clad plates 110 and 2 layers of prepregs 120. The 3 layers of copper clad plates 110 and the 2 layers of prepregs 120 are cross-laminated. A top layer and a bottom layer are copper clad plates 110. An upper surface and a lower surface of each copper clad plate 110 are covered copper circuit 130. The printing circuit board also includes two cylindrical micro-radiators 150, each cylindrical micro-radiator 150 is embedded into a cylindrical hole of the substrate. The height of the micro-radiator 150 is equal to the thickness of the substrate. An upper surface 151 and a lower surface 152 of the micro-radiator are covered by copper foils. A LED chip 160 is installed on the upper surface 151, and the power signal input of the LED chip 160 is electrically connected to the inner circuit of the printing circuit board, and the lower surface 152 of the micro-radiator 150 is insulated from other circuits of the printing circuit board.

A base of the micro-radiator 150 is made from electrical insulating materials, such as alumina ceramic, aluminum nitride ceramic, silicon carbide, diamond, and so on. The thermal conductivity between the upper surface 151 and the lower surface 152 of the micro-radiator 150 can be achieved to 20-1000 W/mk.

When the LED chip 160 is operating, the LED is lighting and emitting heat continuously. The heat is transferred from the upper surface 151 to the lower surface 152 of the micro-radiator 150 by the thermal conductive base, then transferred out of the printing circuit board by copper foil of the lower surface 152.

The printing circuit board of the present invention is not limited by the preferred embodiments, all the equivalent change and modification according to the present invention are covered by the protection scope of the claims. For example:

One or more heating device such as LED elements or integrated circuit chip can be installed on the upper surface 151 of the micro-radiator 150.

The rigid PCB can be connected to the traditional flexible PCB, and a rigid/flexible combined PCB is formed.

The number of the layers of the printing circuit board is not limited to six, the number of the layers of the printing circuit board also can be four, eight or sixteen, and so on.

The copper clad plate 110 is not limited to the two surfaces being both covered by copper circuits, it can be single side covered by copper circuit, it just makes sure the top layer and the bottom layer of the printing circuit board covered by copper circuit.

The micro-radiator 150 is not limited to cylindrical, it also can be elliptic cylindrical, cube-shaped or cylinder shape. When the micro-radiator is cylinder shape, both the upper surface and lower surface are rhombus, triangle or trapezoid, and so on.

The number of the micro-radiators depends on the need of the actual circuit, it can be one or more.

The LED chips or other integrated circuit chips are not limited to connect the inner circuit of the printing circuit board; they also can be connected to the top layer circuit or the bottom layer circuit.

1-2. (canceled)

3. The printing circuit board of claim 1, wherein the micro-radiator is elliptic cylindrical, cube-shaped or cylinder shape, when the microradiator is cylinder shape, both the upper surface and the lower surface are rhombus, triangle or trapezoid.

4-10. (canceled)
